(19) United States
(12) Patent Application Publication
(10) Pub. No.: US 2005/0230829 A1
(43) Pub. Date: Oct. 20, 2005

(54) Semiconductor device

(75) Inventors: Yuji Watanabe, Chuo-ku (JP); Mitsuaki Katagiri, Chuo-ku (JP); Hisashi Tanie, Tsuchiura-shi (JP); Atsushi Nakamura, Shinjuku-ku (JP); Tomohiko Sato, Shinjuku-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC.

(21) Appl. No.: 11/081,658

(22) Filed: Mar. 17, 2005

(30) Foreign Application Priority Data
Mar. 19, 2004 (JP) 2004-079791

(51) Int. Cl. H01L 23/48

(52) U.S. Cl. 257/738; 257/786

(57) ABSTRACT

A semiconductor device is provided with a semiconductor package 2 and a package substrate 5 having lands 8 that electrically connect by way of solder bumps 4 to the semiconductor package 2. A plurality of columns, in each of which a multiplicity of lands 8 are arranged, are formed on the package substrate 5. At least one of the lands 8 that make up columns that are located closest to each of the main sides that make up the outer edges of the semiconductor package has an interconnection 9 that extends from the land 8 along the surface of the package substrate. The interconnection 9 is formed such that the part that contacts the land 8 is located closer to a line that passes through the center of the land 8 and that is orthogonal to a line that connects the center of the land 8 with the center of the semiconductor package 2 than to the line that connects the center of the land 8 with the center of the semiconductor package 2.

### BACKGROUND OF THE INVENTION

1. Field of the Invention

The present invention relates to a semiconductor device having lands for forming electrical connections with semiconductor packages by way of solder bumps.

2. Description of the Related Art

Semiconductor memories are used in a wide variety of information devices such as large-scale computers, personal computers, and portable apparatuses, and the capacity and speed demanded of semiconductor memories increases with each year. Because greater capacity and higher speed are accompanied by an increase in the chip dimensions of the semiconductor memory, semiconductor elements must be packaged with a high density in the limited space of a package substrate. As one technology for realizing high-capacity memory in a limited package area, semiconductor devices are being developed in which CSP (Chip Size Packages), which are semiconductor packages having substantially the same dimensions as the area of semiconductor elements, are being mounted on both surfaces of the package substrate. In such cases, the reliability of the connection parts between the semiconductor package and the package substrate must be ensured.

Japanese Patent Laid-Open Publication No. H11-126795 discloses a semiconductor device of the prior art that relates to the reliability of the connection parts between electronic components and a package substrate.

This semiconductor device of the prior art has a configuration that is provided with: electronic components and a package substrate having lands for electrical connection to these electronic components by way of solder balls. A plurality of columns is formed on the package substrate, a plurality of lands being arranged in each column, and interconnections extend from lands along the surface of the package substrate surface. Interconnections that contact with lands in the outermost columns have contact parts on the outermost positions of each land. In addition, interconnections that contact lands inside these columns have contact parts at positions toward the inside from the outermost position of each land in order to avoid interference with the lands of the outer columns. To prevent the interface angle between the solder balls and the connection parts of the interconnections of lands from becoming an acute angle and the consequent occurrence of a concentration of stress, the publication further discloses a configuration in which lands protrude from the solder resist to make all interface angles obtuse between solder balls and lands.

The coefficient of linear expansion of the electronic components is typically different from that of the package substrate for mounting the electronic components. As a result, when heat load is applied to the device due to the heat generation of the semiconductor device during operation or changes in the ambient temperature, the difference in the amount of thermal deformation between the electronic components and the package substrate produces thermal stress in the connection parts of the electronic components and the package substrate. When this thermal stress is great, there is a danger of low-cycle fatigue in the connection parts and consequent disconnection. In particular, in a semiconductor device having high-density packaging, the dimensional tolerances of the connection parts are small, and ensuring connection reliability therefore becomes a key issue.

In a semiconductor device in which electronic components are connected to the package substrate by a plurality of solder bumps, the difference in the amount of thermal deformation between the electronic components and the package substrate produces a high level of plastic strain on lines in the direction of the center of the electronic component in the solder bumps that are at positions remote from the center of the electronic component, with the resulting problem of a drastic reduction of the life of the connection. In the above-mentioned document, however, countermeasures relating to this problem are not disclosed.

### SUMMARY OF THE INVENTION

It is an object of the present invention to provide a semiconductor device that allows an improvement in the reliability against heat load of the connection parts between a semiconductor package and a package substrate and thus allows greater capacity, higher functionality, and improved space-saving capability.

In the semiconductor device of the present invention, wiring is formed such that contact portions with the lands are located closer to lines that pass through the centers of lands and that are orthogonal to lines that join the centers of lands and the center of semiconductor package than to the lines that join the centers of the lands and the center of the semiconductor package.

The first mode of the present invention is a configuration that is provided with a semiconductor package and a package substrate having lands for electrically connecting to the semiconductor package by way of solder bumps; wherein a plurality of columns are formed on the package substrate with a plurality of the lands being arranged in each column; at least one of the lands that make up the columns that are located on the sides closest to each of main edges that make up the outer edges of the semiconductor package has an interconnection that extends from the land along the surface of the package substrate; and this interconnection is formed with a contact portion with the land that is located closer to a line that passes through the center of the land and that is orthogonal to a line that joins the center of the land and the center of the semiconductor package than to the line that joins the center of the land and the center of the semiconductor package.

A more preferable actual configuration in the above-described first mode of the present invention is as follows:

1) The semiconductor package is formed in a rectangular shape; the lands are formed in a multiplicity of rows and a multiplicity of columns within the plane of projection of the semiconductor package; and each of the interconnections that contact the plurality of lands of the outermost columns and rows are formed such that contact portions with the lands are located closer to lines that pass through the centers of the lands and that are orthogonal to lines that connect the centers of the lands with the center of the semiconductor package than to the lines that connect the centers of the lands with the center of the semiconductor package.

The second mode of the present invention is a configuration provided with a semiconductor package and a package substrate having a plurality of lands for electrically connecting to the semiconductor package by way of solder bumps; wherein at least one of the lands that is located closest to the areas of intersection of the main edges that form the outer edges of the semiconductor package has an interconnection that extends from the land along the surface of the package substrate, and the interconnection is formed such that its contact portion with the land is located closer to the line that passes through the center of the land and that is orthogonal to the line that joins the center of the land with the center of the semiconductor package than to the line that joins the center of the land with the center of the semiconductor package.

A more preferable actual configuration in this second mode of the present invention is as follows:

(1) The semiconductor package is formed in a rectangular shape; the lands are formed in a multiplicity of rows and a multiplicity of columns within the plane of projection of the semiconductor package; and each of the interconnections that contact the plurality of lands in areas closest to the corners of the semiconductor package are formed such that contact portions with the lands are located closer to lines that pass through the centers of the lands and that are orthogonal to lines that connect the centers of the lands with the center of the semiconductor package than to the lines that connect the centers of the lands with the center of the semiconductor package.

A more preferable actual configuration in either of the above-described first or second mode of the present invention is as follows:

(1) The lands are formed in a circular shape having a diameter that is greater than the width of the interconnection, and the solder bumps are connected by contact with the upper surface and side surfaces of the lands.

(2) The lands include signal lands for conveying signals to the semiconductor package and power supply lands or ground lands that connect to the power supply or ground; and lands that have contact portions with the interconnections are signal lands.

(3) The semiconductor packages are arranged on both main surfaces of the package substrate.

(4) The package substrate has outer terminals that are electrically connected to the semiconductor package and that are electrically connected to the outside.

(5) The lands have main surfaces of the lands that confront the semiconductor package side and sidewalls that are adjacent to the main surfaces, and the solder bumps are formed so as to cover a portion of the sidewalls.

The third mode of the present invention is a configuration that is provided with a semiconductor package and a package substrate having lands that electrically connect with the semiconductor package by way of solder bumps; wherein a multiplicity of the lands are arranged in columns and a plurality of these columns are formed on the package substrate; at least one first land of the lands that make up the columns that are located closest to each of the main sides that make up the outer edges of the semiconductor package has a first interconnection that extends from the first land along the surface of the package substrate; the first interconnection has a contact portion with the first land that is located closer to a line that passes through the center of the first land and that is orthogonal to a line that connects the center of the first land and the center of the semiconductor package than to the line that connects the center of the first land with the center of the semiconductor package; at least one second land of the lands that make up columns that are arranged inwardly from the columns that are located closest to the main sides that make up the outer edges of the semiconductor package has a second interconnection that extends from the second land and along the surface of the package substrate; and the second interconnection is formed with a contact portion with the second land that is located closer to a line that passes through the center of the second land and that is orthogonal to a line that connects the center of the second land with the center of the semiconductor package than to the line that connects the center of the second land with the center of the semiconductor package.

According to the present invention, a semiconductor device can be obtained having improved reliability of the connection parts between the semiconductor package and the package substrate against heat load and that enables greater capacity, higher functionality, and better space-saving capability.

### BRIEF DESCRIPTION OF THE DRAWINGS

FIG. 1A is a plan view showing the semiconductor device according to a first working example of the present invention;

FIG. 1B is a side view showing the semiconductor device according to the first working example of the present invention;

FIG. 1C is an enlarged view of portion A in FIG. 1A;

FIG. 2A is an enlarged view showing the vicinity of a land of the package substrate of the first working example;

FIG. 2B is a sectional view taken along line B-B′ of FIG. 2A;

FIG. 3 is a schematic sectional view of the semiconductor package of the first working example;

FIG. 4 is a schematic sectional view of the vicinity of the connection part showing the connection between the semiconductor package and package substrate of the first working example;

FIG. 5A shows the state of the semiconductor device of the first working example before a drop in temperature;

FIG. 5B shows the state of the semiconductor device of the first working example after a drop in temperature;

FIG. 6 shows the range of plastic strain of solder bumps in the connection parts of solder bumps and lands on the surface of the package substrate of the present working example;

FIG. 7 shows an enlargement of one-quarter of the area of the semiconductor package showing the distribution of the range of plastic strain of FIG. 6;

FIG. 8 is a view for explaining the mechanism by which a range of plastic strain of solder occurs in a semiconductor device that relates to the first working example;

FIG. 9A is a plan view showing the semiconductor device according to the second working example of the present invention;

FIG. 9B is a side view showing the semiconductor device according to the second working example of the present invention;

FIG. 9C is an enlargement of portion A in FIG. 9A;

FIG. 10A is a plan view showing the semiconductor device according to the third working example of the present invention;

FIG. 10B is a side view showing the semiconductor device according to the third working example of the present invention;

FIG. 10C is an enlargement of portion A in FIG. 10A;

FIG. 11A is a plan view showing the semiconductor device according to the fourth working example of the present invention;

FIG. 11B is a side view showing the semiconductor device according to the fourth working example of the present invention;

FIG. 11C is an enlargement of portion A in FIG. 11A;

FIG. 12A is a plan view showing the semiconductor device according to the fifth working example of the present invention;

FIG. 12B is a side view showing the semiconductor device according to the fifth working example of the present invention;

FIG. 12C is an enlargement of portion A in FIG. 12A;

FIG. 13A is a schematic sectional view of one mode of the semiconductor package that is used in the semiconductor device of the sixth working example of the present invention;

FIG. 13B is a schematic sectional view of another mode of the semiconductor package of the sixth working example;

FIG. 14A is a schematic sectional view of one mode of the semiconductor packages that are used in the semiconductor device of the seventh working example of the present invention;

FIG. 14B is a schematic sectional view of another mode of the semiconductor packages of the seventh working example;

FIG. 15 is an explanatory view of the mechanism by which the range of plastic strain in solder occurs in a semiconductor device that relates to the seventh working example;

FIG. 16A is a plan view showing the semiconductor device according to the eighth working example of the present invention;

FIG. 16B is a side view showing the semiconductor device according to the eighth working example of the present invention;

FIG. 17A is a plan view showing the semiconductor device according to the ninth working example of the present invention; and

FIG. 17B is a side view showing the semiconductor device according to the ninth working example of the present invention.

### DETAILED DESCRIPTION OF THE PREFERRED EMBODIMENTS

The following explanation regards a plurality of working examples of the present invention with reference to the accompanying figures. In the figure of each working example, the same reference numerals are used to identify the same or equivalent parts.

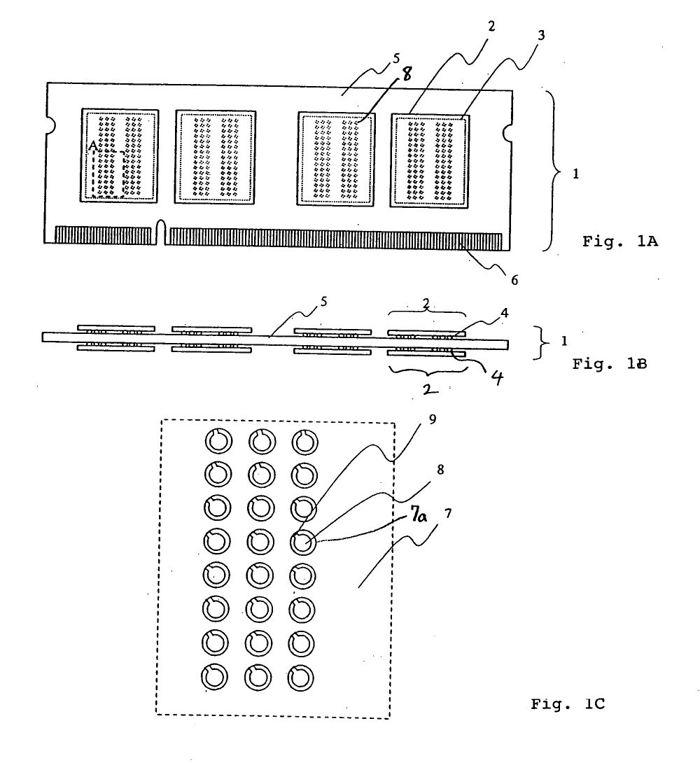

The following explanation regards the first working example of the present invention with reference to FIGS. 1-8.

Explanation first regards the overall configuration of the semiconductor device of the present working example with reference to FIG. 1. FIGS. 1A-1C are views showing the semiconductor device of the first working example of the present invention. FIG. 1A is an overall plan view of the semiconductor device, FIG. 1B is a side view, and FIG. 1C is an enlargement of portion A in which the semiconductor packages of FIG. 1A have been omitted.

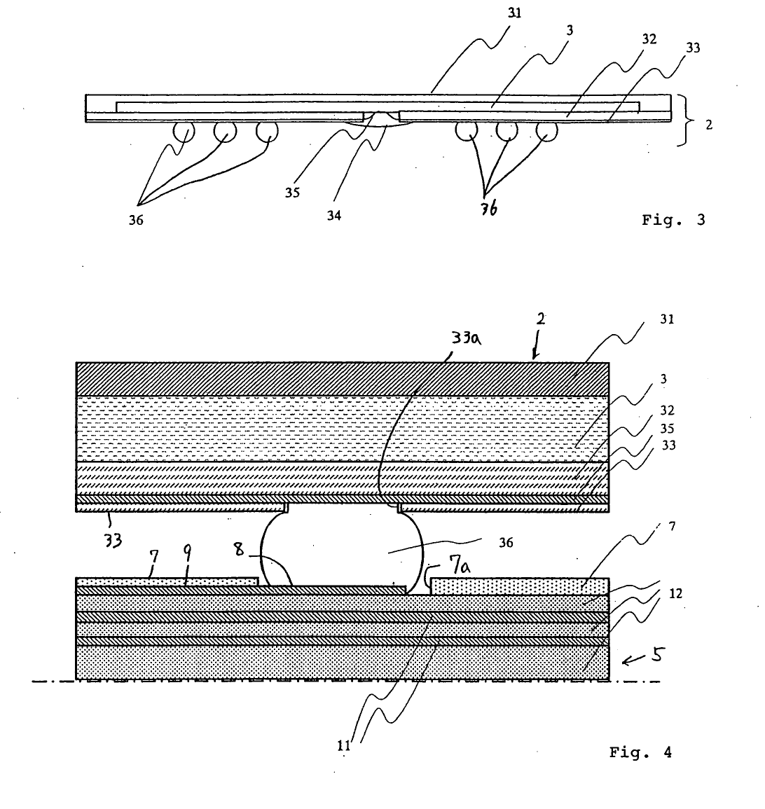

As shown in FIG. 1A, semiconductor device 1 is a configuration provided with a plurality of semiconductor packages 2 having semiconductor elements 3; and package substrate 5 on which these semiconductor packages 2 are mounted on the main surfaces by way of solder connection parts 4. Package substrate 5 has a multiplicity of lands 8 that are electrically connected to semiconductor elements 3 of semiconductor packages 2 by way of solder connection parts 4, and interconnections 9 that extend from each of these lands 8 along the surface of the package substrate. Solder connection parts 4 are composed of solder bumps 36 (see FIG. 4) that will be explained hereinbelow.

Semiconductor device 1 of the present working example is a DRAM memory module based on SO-DIMM standards.

Mounting eight DDR2-DRAM semiconductor packages 2 each having a capacity of 512 Mbit on package substrate 5 results in a capacity of 0.5 Gbyte for the entire memory module. The planar dimension of each semiconductor package 2 is approximately 11 mm×13 mm, and semiconductor element 3 having planar dimensions of approximately 10 mm×12 mm are mounted within each semiconductor package 2. Semiconductor packages 2 and package substrate 5 are connected by means of solder connection parts 4 that are arranged in a grid at a spacing of approximately 0.8 mm directly below semiconductor packages 2.

As shown in FIG. 1A and FIG. 1B, a multiplicity (specifically, four on each side and eight on both sides) of semiconductor packages 2 is arranged on both main surfaces of package substrate 5. These semiconductor packages 2 are mounted side by side at symmetrical positions on both sides of package substrate 5, which is a horizontally long rectangle in shape. Each semiconductor package 2 is formed in a vertically long rectangular shape, the four sides of the periphery being the main sides.

As shown in FIG. 1A, lands 8 that are formed on package substrate 5 are formed in a multiplicity of columns and a multiplicity of rows (specifically, 6 columns and fifteen rows) within the plane of projection of the semiconductor package 2. Each column of lands 8 is provided at equal spacing. Each row of lands 8 is provided at equal spacing with the exception of a wide space in the central portion. Lands 8 of each column and each row are arranged in a grid having slightly wider spacing in only the central portion.

As shown in FIG. 1C, the surface of package substrate 5 is provided with: circular lands 8 for connecting semiconductor package 2; interconnections 9 for establishing electrical conduction between semiconductor package 2 and package substrate 5; and solder resist 7 for preventing the wetting and spread of solder connection parts 4. Lands 8 must realize a solder connection with solder connection parts 4, and solder resist 7 is therefore not provided on the upper surface and periphery of lands 8. In other words, holes 7a that are slightly larger in diameter than lands 8 are formed in solder resist 7 at parts in which lands 8 are located. By means of these holes, lands 8 and portions of interconnections 9 are exposed on the surface before solder connection parts 4 are soldered.

Interconnections 9 have a width that is much narrower than the diameter of lands 8, and are led out from lands 8. Interconnections 9 are formed such that contact parts with lands 8 are located closer to lines that pass through the centers of lands 8 and that are orthogonal to lines that join the centers of lands 8 and the center of semiconductor package 2 than to the lines that join the centers of lands 8 and the center of semiconductor package 2. This configuration holds for all interconnections 9 that contact lands 8.

In semiconductor device 1 that has this configuration, interconnections 9 that are led from lands 8 that are provided on the surface of package substrate 5 are led in a direction that is substantially orthogonal to the central direction of each mounted semiconductor package 2. Details regarding this point are explained hereinbelow.

In addition, outside terminals 6 for connecting to an outside socket that is connected to outside circuits are provided on one of the longer sides of package substrate 5. Interconnections 9 connect to outside terminals 6 either directly or indirectly by way of other constituent elements.

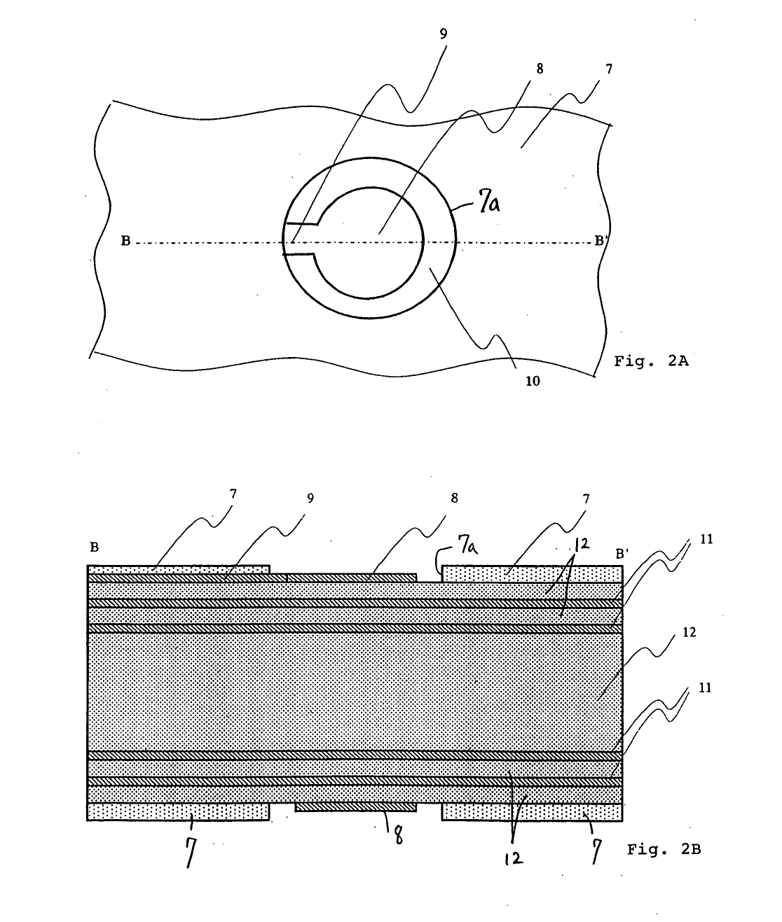

The following explanation regards the actual configuration of package substrate 5 with reference to FIG. 2A and FIG. 2B. FIG. 2A is a plan view of a land portion of package substrate 5, and FIG. 2B is a schematic sectional view taken along line B-B′ of FIG. 2A.

As shown in FIGS. 2A and 2B, solder resist 7 is applied to the surface of package substrate 5, but in the vicinity of land 8, hole 7a is provided in a substantially circular spot in which solder resist 7 is not applied. As a result, an epoxy resin portion of glass fabric-based epoxy resin base 12 is exposed on the surface of package substrate 5 in the vicinity of land 8. This arrangement of solder resist 7 separate from land 8 allows the bonding of solder connection part 4 to the upper surface and side surfaces of land 8. In addition, land 8 is constituted from a copper base metal that is plated with nickel. Interconnection 9 is led from one location of land 8 and covered by solder resist 7 at positions that are separate from land 8. Land 8 and interconnection 9 are formed as a single unit by the same material and have the same thickness, and land 8 and interconnection 9 can therefore be more easily formed.

As shown in FIG. 2B, package substrate 5 is a FR-4 substrate approximately 1 mm thick and having six interconnection layers, has four internal interconnection layers 11 within glass fabric-based epoxy resin base 12 as well as lands 8 and interconnections 9 on both surfaces. Here, the thickness of interconnections 9 and lands 8 on the surface of package substrate 5 is approximately 20 μm, and solder resist 7 that is applied to the surface of the package substrate is provided several μm thicker than interconnections 9 and lands 8, whereby the exposure of interconnections 9 in the surface of package substrate 5 can be prevented.

The following explanation regards the actual configuration of semiconductor package 2 with reference to FIG. 3. FIG. 3 is a schematic sectional view of semiconductor package 2 of the present working example.

Semiconductor package 2 is configured by connecting the active surface of semiconductor element 3 and tape 33 by way of elastomer 32 and then sealing with molded resin 31. Copper inner leads 35 are provided between tape 33 and elastomer 32 and connected to semiconductor element 3 in the vicinity of the center of semiconductor package 2 to establish electrical conduction. In addition, the vicinity of the connection parts between inner leads 35 and semiconductor element 3 is further sealed by potting resin 34. Solder bumps 36 that are composed of solder balls are further bonded to prescribed locations (positions that correspond to lands 8) of semiconductor package 2.

The following explanation regards the bonding structure of package substrate 5 and semiconductor package 2 with reference to FIG. 4. FIG. 4 is a schematic sectional view showing the vicinity of the connection part with semiconductor package 2 connected to package substrate 5 of the present working example.

Molded resin 31 that is arranged at the uppermost position of semiconductor package 2 is an epoxy resin having a thickness of approximately 150 μm. Semiconductor element 3 that is arranged below molded resin 31 is silicon having a thickness of approximately 280 μm, and the active surface having a DRAM circuit is arranged on the lower surface. Elastomer 32 having low elasticity and a thickness of approximately 150 μm is provided below semiconductor element 3, and the arrangement of elastomer 32 below semiconductor element 3 allows the difference in the amount of thermal deformation between semiconductor element 3 and other parts to be absorbed by the deformation of elastomer 32. Inner leads 35 of copper approximately 20 μm thick are further arranged below elastomer 32, and polyimide tape 33 approximately 50 μm thick is further arranged below inner leads 35.

Holes 33a having a diameter of approximately 350 μm are provided in tape 33, and solder bumps 36 and inner leads 35 are connected via these holes 33a. The connection of solder bumps 36 with lands 8 on the surface of package substrate 5 establishes electrical conduction between semiconductor package 2 and package substrate 5. Solder bumps 36 bond not only with the surfaces of lands 8 but the side surfaces as well, and the bonding strength is therefore increased over a case in which only the surfaces are bonded, obtaining an improvement in the life of the connections.

However, in the direction in which interconnections 9 are provided, the side surfaces of lands 8 are not exposed and solder bumps 36 therefore cannot bond with the side surfaces of lands 8. As a result, the bonding strength in the direction in which interconnections 9 are provided is less than that for other directions. In the direction in which interconnections 9 are provided, there is a danger of the occurrence not only of semicircle connection defects, but also of connection defects caused by breaks in interconnections 9. The present working example has been configured with consideration given to these points.

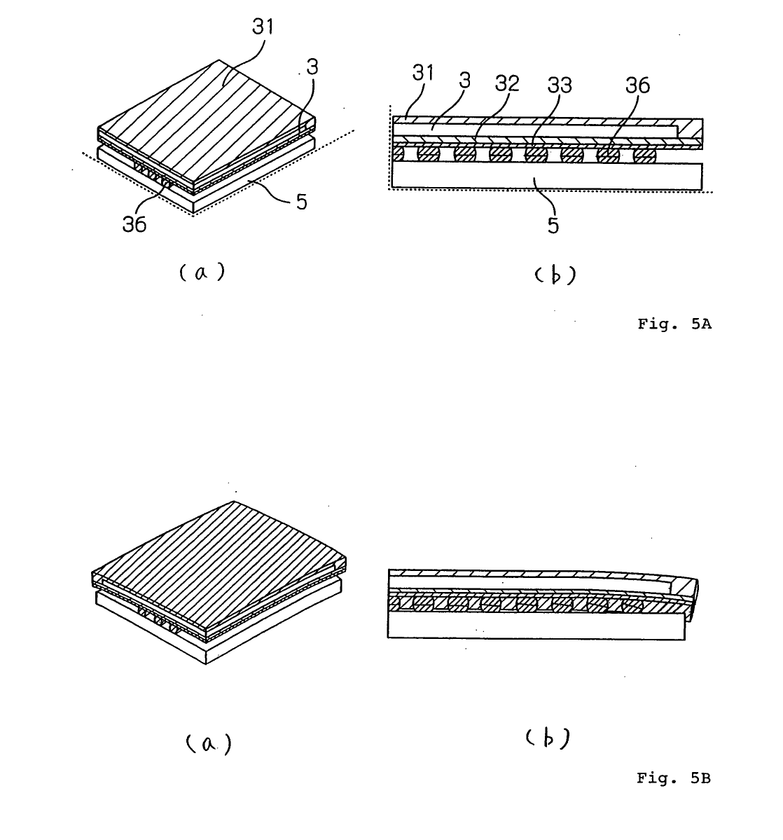

The following explanation regards the deformation during changes in temperature (during drops in temperature) of semiconductor device 1 with reference to FIGS. 5A and 5B. FIG. 5A shows the state before a drop in the temperature of semiconductor device 1, and FIG. 5B shows the state following a drop in the temperature of semiconductor device 1. In addition, FIGS. 5A and 5B take one of the eight semiconductor packages 2 that are mounted on package substrate 5 and, taking advantage of the symmetry of shape, show just one-quarter of semiconductor package 2. Further, due to the symmetry of shape on the two sides of the package substrate, FIG. 5A and FIG. 5B show one-half of the form taking the symmetry around the center of package substrate 5 in the direction of thickness. FIG. 5A (a) and FIG. 5B (a) are perspective views, and FIG. 5A (b) and FIG. 5B (b) are side sectional views.

When semiconductor device 1 experiences a drop in temperature, package substrate 5 has a larger coefficient of linear expansion than semiconductor package 2 and a difference in the amount of thermal deformation therefore occurs which generates load in the shear direction in solder bumps 36.

When solder bumps 36 are arranged substantially uniformly with respect to semiconductor package 2, the load exerted on solder bumps 36 in the direction of shear increases with increasing distance from the central position of semiconductor package 2, and solder bumps that are distant from the central position of semiconductor package 2 therefore undergo the greatest deformation.

Mounting semiconductor packages 2 on both surfaces of package substrate 5 limits warping of package substrate 5. On the other hand, warping of semiconductor package 2 is limited in the vicinity of the central portion of semiconductor package 2 but warping having a convex curvature occurs on the periphery of semiconductor package 2 and the periphery of semiconductor package 2 is therefore deformed downward. This deformation occurs because the connection to package substrate 5 by a plurality of solder bumps 36 in the vicinity of the central portion of semiconductor package 2 restricts warping of the semiconductor package 2, while in the peripheral portion of semiconductor package 2, the restraint due to solder bumps 36 is decreased and the differences in coefficients of linear expansion between semiconductor element 3 and elastomer 32 or tape 33 cause warping that has an upward convex curvature.

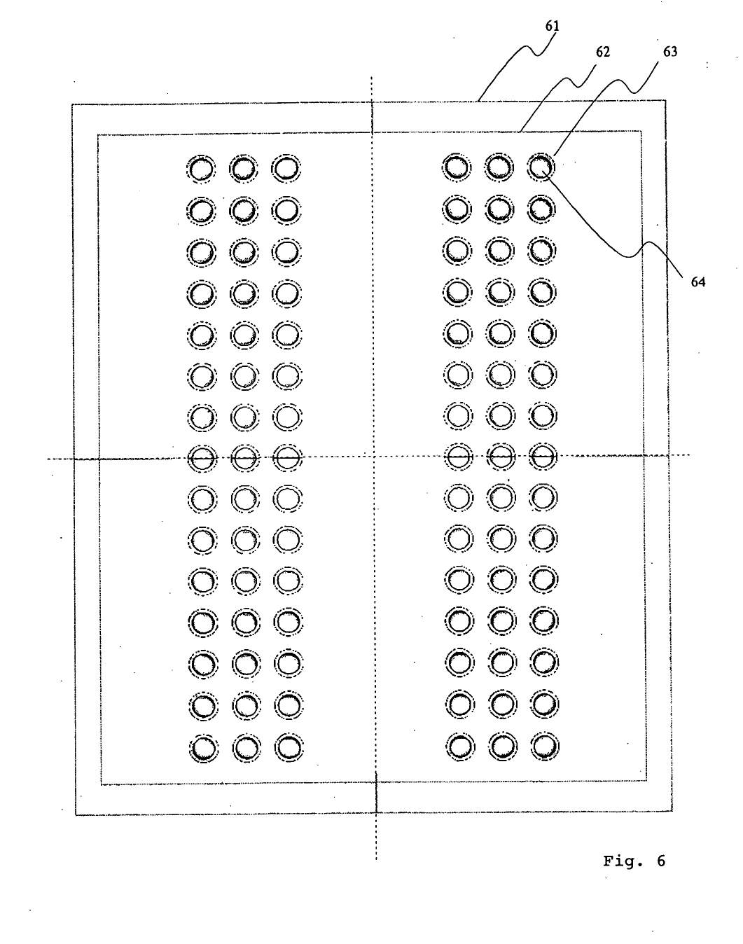

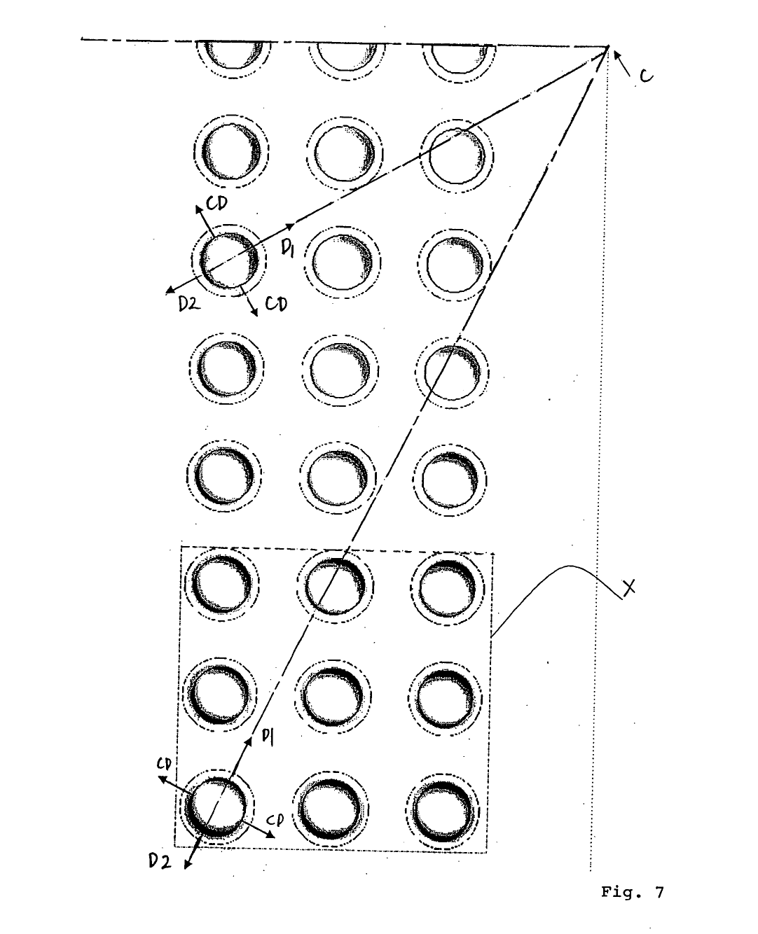

The following explanation regards the plastic strain of solder bumps 36 in the connection parts between lands 8 on the surface of package substrate 5 and solder bumps 36 with reference to FIGS. 6 and FIG. 7. FIG. 6 shows the range of plastic strain of solder bumps 36 in the connection parts between solder bumps 36 and lands 8 on the surface of package substrate 5 in the present working example, and FIG. 7 shows an enlargement of the distribution of the range of plastic strain of FIG. 6 for one-quarter of the area of semiconductor package 2. In this case, the range of plastic strain is the strain that results from plastic deformation of the solder that increases for each cycle when heat load is applied in a temperature cycling test. It is known that the greater this value, the greater the reduction of the life of the connection.

In FIG. 6 and FIG. 7, areas with darker colors indicate a greater range of plastic strain. The distribution of this range of plastic strain is for a condition in which interconnections 9 are not provided that are led out from lands 8. In order to clarify the positions of solder bumps 36, FIG. 6 shows semiconductor package outer form 61, semiconductor element outer form 62, solder bump outer form 63, and solder plastic strain distribution 64 at connection parts with package substrate-side lands.

As can be clearly seen from FIG. 6 and FIG. 7, the range of plastic strain for solder bumps 36 increases with increasing distance from the center C of semiconductor package 2. In other words, solder bumps 36 that are closer to the main sides, which are the outer edge of semiconductor package 2, are subject to a greater range of plastic strain. Accordingly, solder bumps 36 that are closer to the corners of semiconductor package 2 are subject to a greater range of plastic strain.

In addition, areas having a large range of plastic strain can be seen at the portions of circumferences of solder bumps 36 that are close to the lines that join the centers of lands 8 to the center C of semiconductor package 2, and areas having a small range of plastic strain can be seen at the portions of circumferences of solder bumps 36 that are close to lines that pass through the centers of lands 8 and that are orthogonal to lines that join the centers of the lands to center C. This trend becomes more conspicuous with increasing distance from the center of semiconductor package 2, i.e., is more dramatic with increasing proximity to the main sides that are the outer edges of semiconductor package 2. Accordingly, for solder bumps 36 that are close to corners at which the main edges of semiconductor package 2 intersect, areas in which the range of plastic strain is particularly large can be seen in the direction D1 toward the center of semiconductor package 2 and in the direction that is rotated 180° C. from that direction, i.e., the direction D2 toward the corner of semiconductor package 2 from portions that are close to lines that join the centers of solder bumps 36 and the center of semiconductor package 2. In the present working example, solder bumps 36 are provided in six columns (three columns on one side) on each semiconductor package 2, and the range of plastic strain is particularly large for the three solder bumps 36 that are lowermost in FIG. 7. This occurrence of a large range of plastic strain is due to the greater distance from the center of semiconductor package 2.

Although the range of plastic strain that occurs decreases as the center of semiconductor package 2 is approached from these solder bumps 36 (by moving upward in the figure), this range of plastic strain does not decrease markedly even with the movement of 1-2 pitches (0.8 mm/pitch in the present working example). This lack of change is due to the great distance between the center of semiconductor package 2 and solder bumps 36 in the corner portions, whereby despite a decrease of 1-2 pitches in the distance from the center of semiconductor package 2, the absolute value of the amount of change in distance is small and the effect of a large decrease in the range of plastic strain that occurs therefore cannot be seen. The effect of decrease of the range of plastic strain in solder bumps 36 in the outermost columns is particularly small.

Due to these factors, the reliability of connections must be ensured against the great range of plastic strain that occurs in at least solder bumps 36 that are arranged in the corner portions, and more preferably, the reliability of connections is preferably ensured against the great range of plastic strain that occurs in solder bumps 36 in the outermost columns. In the present working example, interconnections 9 that contact lands 8 that are located closest to the areas of intersection of the main sides, which form the outer edge of the semiconductor package, are of course formed such that contact parts with lands 8 are located closer to lines that pass through the centers of lands 8 and that are orthogonal to lines that join the centers of lands 8 and the center of semiconductor package 2 than to lines that join the centers of lands 8 and the center of semiconductor package 2; and interconnections 9 that contact all lands 8 that include outermost columns are formed such that the parts that contact lands 8 are closer to lines that pass though the centers of lands 8 and that are orthogonal to lines that join the centers of lands 8 and the center of semiconductor package 2 than to the lines that join the centers of lands 8 and the center of semiconductor package 2.

At solder bumps 36 located close to the center of semiconductor package 2, on the other hand, areas having a great range of plastic strain are found in portions close to center direction D1 of semiconductor package 2, while the range of plastic strain in the portions on the opposite side is small.

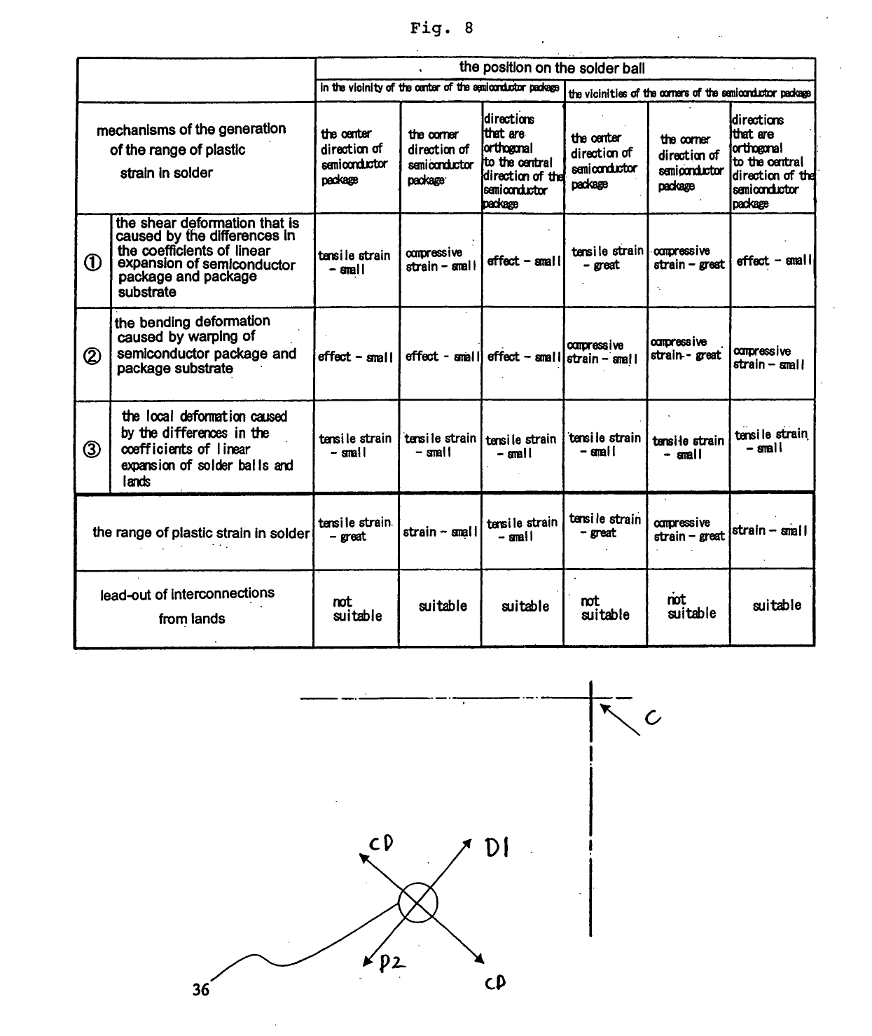

The mechanisms by which the direction in which the range of plastic strain is great changes according to the position of the solder bumps will next be explained while referring to FIG. 8. FIG. 8 is a view for explaining the mechanisms of the generation of the range of plastic strain in solder of a semiconductor device that relates to the present working example.

The three chief causes for the generation of a range of plastic strain in the portions at which solder bumps 36 bond to lands 8 on the surface of package substrate 5 are: the shear deformation caused by differences in the coefficients of linear expansion of semiconductor package 2 and package substrate 5; the bending deformation caused by warping of semiconductor package 2 and package substrate 5; and the local deformation caused by the differences in the coefficients of linear expansion of solder bumps 36 and lands 8. The range of plastic strain that is generated from these causes differs according to the direction and the position of the solder bumps. These factors are brought together in FIG. 8.

First, the shear deformation that is caused by the differences in the coefficients of linear expansion of semiconductor package 2 and package substrate 5 is generated with center position C of semiconductor package 2 as the center when solder bumps 36 are arranged substantially uniformly with respect to semiconductor package 2. In other words, shear deformation does not occur at center position C of semiconductor package 2, a relatively small range of plastic strain occurs in solder bumps 36 that are in the vicinity of the center of the semiconductor package, and a large range of plastic strain occurs in solder bumps 36 that are in the vicinities of the corners of the semiconductor package that are far from the center position of semiconductor package 2. At this time, package substrate 5 has a higher coefficient of linear expansion than semiconductor package 2, whereby a drop in temperature results in the generation of tensile strain in the center direction D1 of semiconductor package 2 in solder bumps 36 and compressive strain in the corner direction D2 of semiconductor package 2.

The effect of this strain is relatively small in directions CD that are orthogonal to the central direction of the semiconductor package.

Regarding the bending deformation that is caused by warping of semiconductor package 2 and package substrate 5, warping of package substrate 5 is small due to the mounting of semiconductor packages 2 on both surfaces of package substrate 5 in the present working example.

However, as shown in FIG. 5, semiconductor package 2 undergoes little warping in the vicinity of the center of semiconductor package 2 but experiences upward convex warping in the corners of semiconductor package 2. Thus, although the effect of warping upon solder bumps 36 is limited in the vicinity of the center of semiconductor package 2, solder bumps 36 in the vicinities of the corners of semiconductor package 2 are pressed by the semiconductor package and are therefore subject to compressive strain. At this time, the corner direction D2 of semiconductor package 2 undergoes the greatest warping of semiconductor package 2 and this direction is therefore subject to the greatest compressive strain.

Next, regarding the local deformation caused by the differences in coefficients of linear expansion of solder bumps 36 and lands 8, lands 8 that are made of copper are used in the present working example, and the coefficient of linear expansion of lands 8 is therefore lower than for solder bumps 36. Thus, when the temperature drops, solder bumps 36 are subject to the tensile load from lands 8 and solder bumps 36 are therefore subject to tensile strain in any direction. However, this tensile strain results from differences in local physical properties and the absolute value of the strain that occurs is small.

Putting together these results, solder bumps 36 in the vicinity of the central portion of semiconductor package 2 are subject to great strain in the center direction D1 of semiconductor package 2 and solder bumps 36 in the vicinities of the corners of semiconductor package 2 are subject to great strain in the center direction D1 and corner direction D2 of the semiconductor package.

When interconnections 9 are led out from lands 8 of the package substrate, as previously described, the bonding strength decreases in the direction in which interconnections 9 are led out more than in other directions. When leading out interconnections 9, avoiding the direction in which the above-described strain is great is therefore effective for preventing disconnections of solder bumps 36 and interconnections 9 and for improving connection reliability.

For these reasons, the direction of lead-out of interconnections 9 from all lands 8 in the present working example is the direction that is orthogonal to direction of the center of the semiconductor package in which the strain is small.

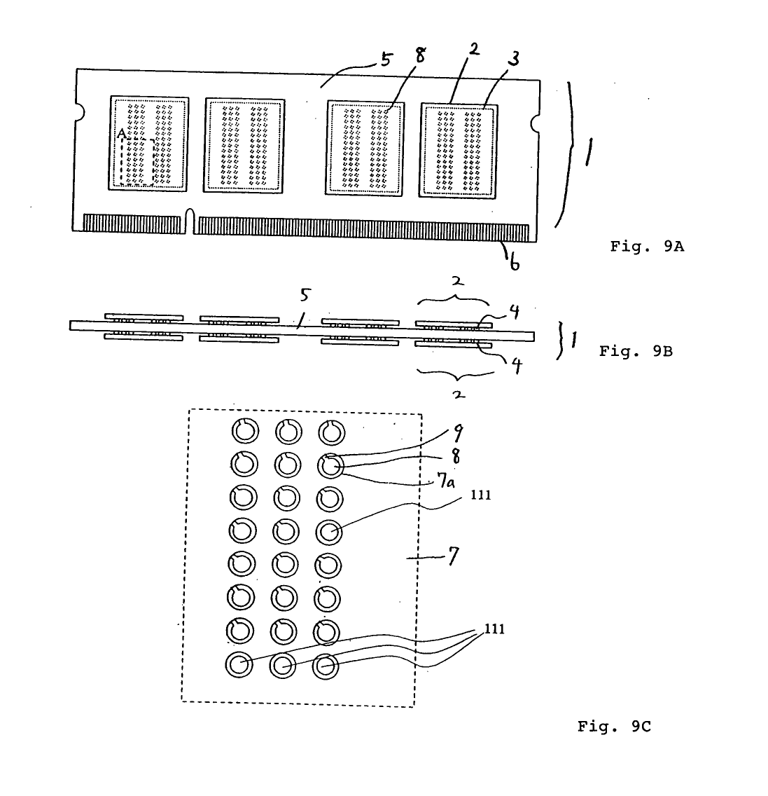

The following explanation regards the second to ninth working examples with reference to FIGS. 9A-17B. The second to ninth working examples differ from the first working example as described hereinbelow, and are otherwise basically the same as the first working example.

Second Working Example

FIG. 9A is an overall plan view of the semiconductor device of the second working example of the present invention, FIG. 9B is a side view of the semiconductor device, and FIG. 9C is an enlarged view of portion A in which the semiconductor packages of FIG. 9A have been omitted.

The second working example differs from the first working example in that, while interconnections 9 are provided at all lands 8 in the first working example, in the second working example, lands 111 that are electrically unconnected and do not use interconnections 9 are provided in a portion of lands 8. These lands 111 that do not use interconnections 9 do not have an electrical function, but the provision of these lands 111 can improve the reliability of other connection parts in which electrical conduction has been established. In particular, the provision of lands 111 in the corners or peripheral portions of semiconductor package 2 can improve the reliability of the connection parts that are arranged inside these lands 111 (closer to the center of semiconductor package 2). Despite this presence of unconnected lands 111, providing interconnections 9 that are led out from other lands 8 in the direction in which the range of plastic strain of solder is small according to the previously described mechanisms can improve the connection reliability. In addition, although unconnected lands 111 are arranged in a grid in the second working example, these lands 111 can be arranged at positions that are different from the grid points.

Third Working Example

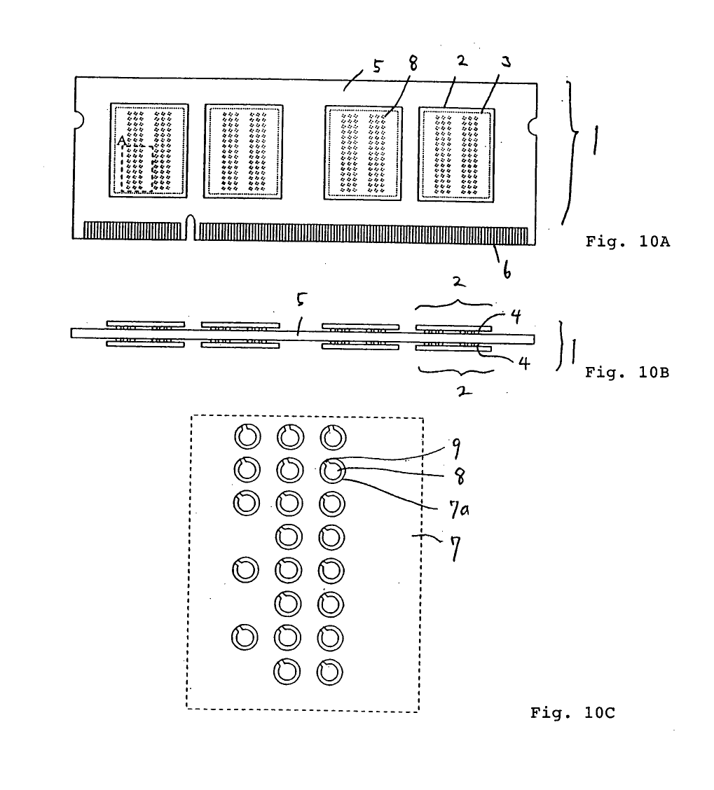

FIG. 10A is an overall plan view of the semiconductor device of the third working example of the present invention, FIG. 10B is a side view of the semiconductor device, and FIG. 10C is an enlarged view of portion A in which the semiconductor packages of FIG. 10A have been omitted.

The third working example differs from the first working example in that, while all lands 8 are arranged in a grid in the first working example, some locations are not provided with lands 8 in the third working example. When the number of connection pins that is electrically required is less than the number of grid points, not providing lands 8 in a portion of the grid can facilitate the routing of interconnections on the package substrate and can increase the freedom of the mounting position of the package. In this case, there is a concern that the range of plastic strain that occurs at solder bumps 36 will increase when compared with a case in which lands 8 are provided at all points in a grid. However, the mechanism for this generation of strain is the same as in the previously described first working example, and providing interconnections 9 in the direction in which the range of plastic strain of the solder is small as in the first working example enables an improvement in the connection reliability.

Fourth Working Example

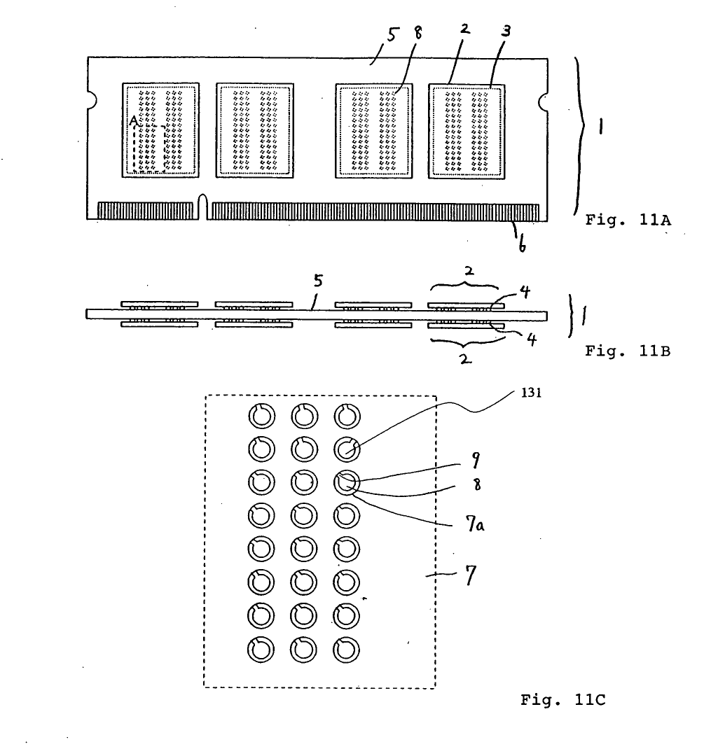

FIG. 11A is an overall plan view of the semiconductor device of the fourth working example of the present invention, FIG. 11B is a side view of the semiconductor device, and FIG. 11C is an enlarged view of portion A in which the semiconductor packages of FIG. 11A have been omitted.

The point of difference between the first working example and the fourth working example is that, while interconnections 9 that are led out from all lands 8 are provided in the direction in which the range of plastic strain of the solder is small in the first working example, in the fourth working example, a portion of interconnections 9 are provided in a direction in which the range of plastic strain of the solder is great. Lands 8 in which interconnections 9 are provided in a direction in which the range of plastic strain of the solder is great are power supply pins 131. Arranging interconnections in a direction in which the range of plastic strain of the solder is great raises the concern that these connection parts will not last as long as other connection parts. In the case of power supply pins 131, however, a plurality of pins exist that have the same voltage, and the semiconductor device can still operate despite the failure of the connection part of any particular pin.

In addition, the current that passes through power supply pins 131 is greater than the current in signal pins for transmitting signals and the use of wide interconnections 9 is therefore necessary. The use of wide interconnections 9 interferes with the ability to route interconnections 9 on the surface of package substrate 5, and leading interconnections 9 in the ideal direction can therefore be problematic. For these reasons, interconnections 9 can be provided in a direction in which the range of plastic strain of solder is great for a portion of power-supply pins as long as this is for a plurality of power supply pins having the same voltage. However, even in this case, it is not possible to provide interconnections 9 in a direction in which the range of plastic strain of solder is great for all power supply pins having the same voltage.

Fifth Working Example

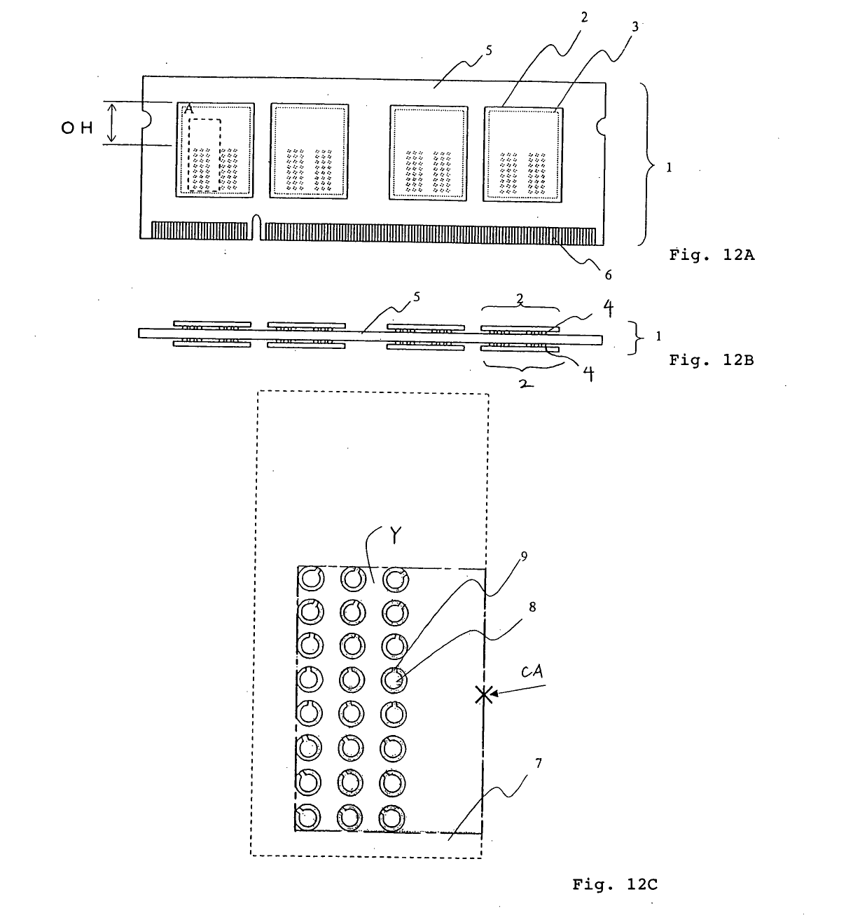

FIG. 12A is an overall plan view of a semiconductor device of the fifth working example of the present invention, FIG. 12B is a side view of the semiconductor device, and FIG. 12C is an enlarged view of portion A in which the semiconductor packages of FIG. 12A have been omitted.

The point of difference between the first working example and the fifth working example is the large offset of the arrangement of lands 8 with respect to semiconductor package 2 in the fifth working example. When the arrangement of lands 8 is offset in this way, the position that is the center of the shear deformation that is caused by the difference in coefficients of linear expansion of semiconductor package 2 and package substrate 5, i.e., the position at which shear deformation does not occur, diverges from the center position of semiconductor package 2. This divergence occurs because the “shear deformation that is caused by the difference in coefficients of linear expansion of semiconductor package 2 and package substrate 5” is not influenced by the portions that lack solder connection parts (parts that overhang from the solder connection parts).

Accordingly, in a semiconductor package 2 in which the arrangement of lands 8 is offset with respect to semiconductor package 2 as in the fifth working example, the connection reliability of semiconductor package 2 and package substrate 5 can be ensured by determining the direction of interconnections 9 based on the central position of the area that is enclosed by the outermost areas of the connection parts, as shown in the figure.

Sixth Working Example

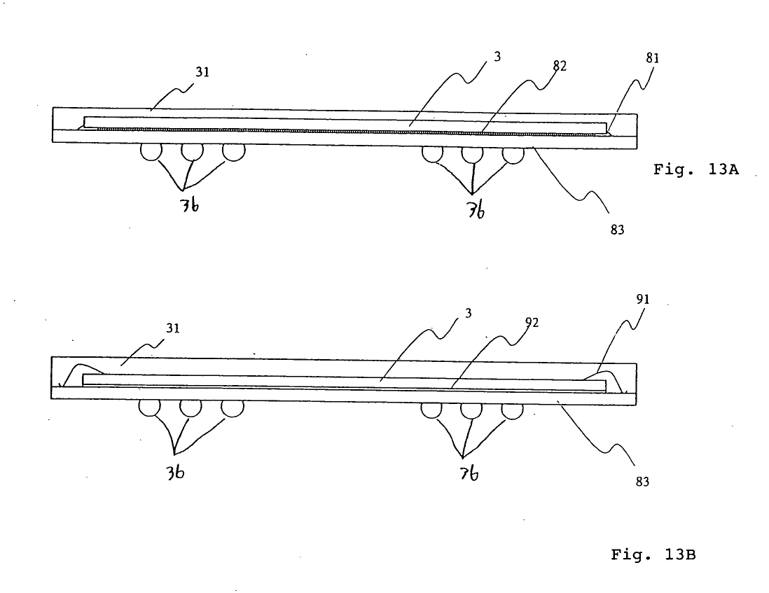

FIGS. 13A and 13B are schematic sectional views of semiconductor package 2 that is used in semiconductor device 1 of the sixth working example of the present invention. The point of difference between the first working example and the sixth working example is the provision of primary substrate 83 and the lack of elastomer 32 in semiconductor package 2 in the sixth working example.

FIG. 13A shows semiconductor package 2 that shows one mode of the sixth working example. In this semiconductor package 2, the active surface of semiconductor element 3 is arranged on the side of primary substrate 83, and electrical conduction of primary substrate 83 with semiconductor element 3 is established by means of flip-chip connection of semiconductor element 3 and primary substrate 83. In contrast with the first working example, this configuration is not provided with elastomer 32, which absorbs the differences in the amount of thermal deformation between semiconductor element 3 and other members, and this raises some concern regarding a drop in the connection reliability of the flip-chip connection parts.

However, the application of underfill material 81 between semiconductor element and primary substrate ensures the reliability of the flip-chip connection parts.

FIG. 13B shows semiconductor package 2 that shows another mode of the sixth working example. In this semiconductor package 2, the active surface of semiconductor element 3 is arranged on the side opposite primary substrate 83, and bonding wires 91 are used to establish electrical conduction between semiconductor element 3 and primary substrate 83. In this configuration, semiconductor element 3 and primary substrate 83 are connected by die bonding parts 91. In this way, the differences in the amount of thermal deformation between semiconductor element 3 and other parts can be absorbed by the deformation of the die bonding wires, and the connection reliability can thus be ensured.

Even in a configuration that lacks elastomer 32 in semiconductor package 2, the mechanisms for the generation of a range of plastic strain of solder of the connection parts between semiconductor package 2 and package substrate 5 are the same three mechanisms that were shown in the first working example. Accordingly, when the semiconductor package of the sixth working example is mounted on package substrate 5, leading out land interconnections in the same direction as in the first working example can ensure the connection reliability of semiconductor package 2 and package substrate 5.

Seventh Working Example

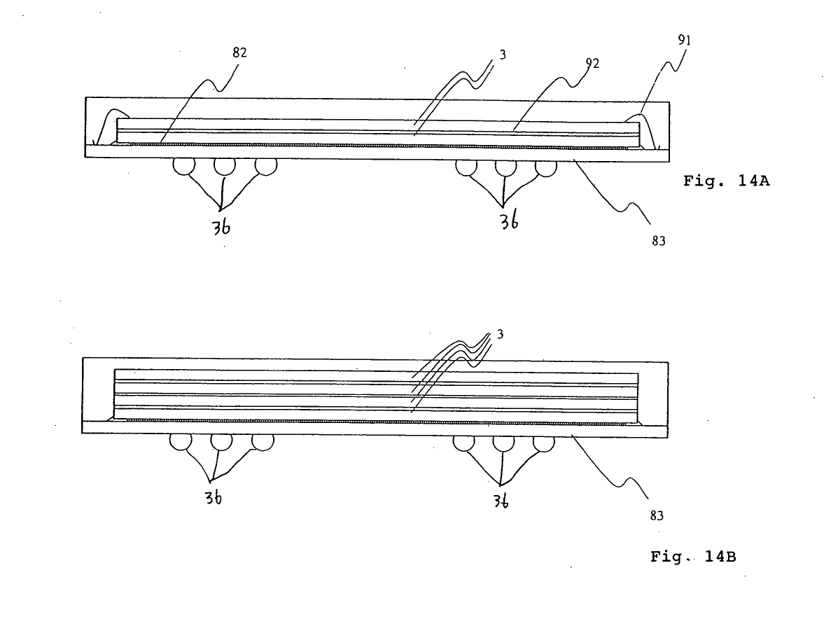

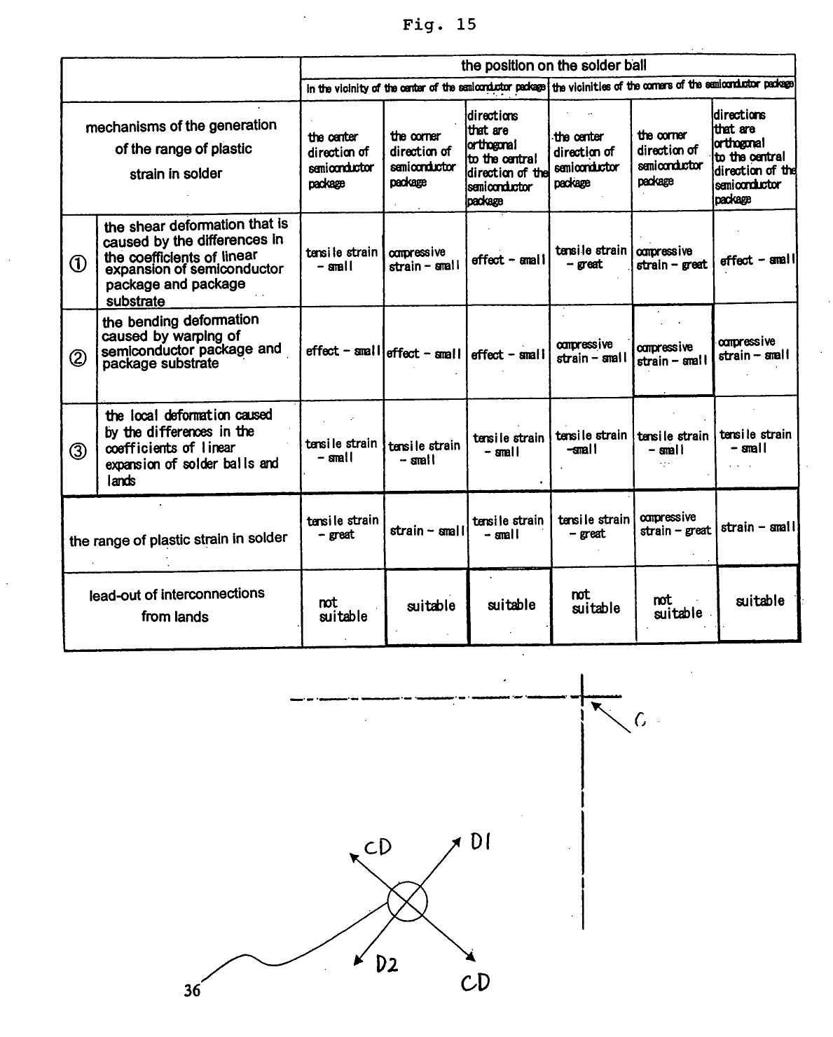

FIGS. 14A and FIG. 14B are schematic sectional views of semiconductor package 2 that is used in semiconductor device 1 of the seventh working example of the present invention, and FIG. 15 is a view for explaining the mechanism of the generation of a range of plastic strain of solder of a semiconductor device that relates to the seventh working example.

The seventh working example differs from the first working example in that the seventh working example lacks elastomer 32 in semiconductor package 2 but has primary substrate 83, and further has a plurality of semiconductor elements 3 inside semiconductor package 2. As one method for mounting many semiconductor elements 3 in a limited package area, it is effective to incorporate a plurality of semiconductor elements 3 in one semiconductor package 2 as in the seventh working example.

FIG. 14A shows semiconductor package 2 that represents one mode of the seventh working example. In this semiconductor package 2, two semiconductor elements 3 are incorporated inside semiconductor package 2, the lower semiconductor element 3 being connected to primary substrate 83 by means of flip-chip bonding 82, and the upper semiconductor element 3 being connected to primary substrate 83 by means of bonding wires 91.

FIG. 14B shows semiconductor package 2 that represents another mode of the seventh working example. In this semiconductor package 2, four semiconductor elements 3 are incorporated in semiconductor package 2, each of semiconductor elements 3 being connected by means of through-type electrodes that are provided inside semiconductor elements 3.

In semiconductor package 2 that is configured in this way, the total thickness of semiconductor elements 3 is greater than a configuration having only one semiconductor element 3, and the greater flexural rigidity of semiconductor package 2 impedes warping.

FIG. 15 organizes the mechanisms and effects of the generation of the range in plastic strain in the solder of the connection parts of semiconductor package 2 and package substrate 5 in this case. The chief mechanisms for the generation of plastic strain are the same three types as FIG. 8 of the first working example, but because warping of semiconductor package 2 is reduced in the present working example, the effect of the mechanism of “bending caused by warping of the semiconductor package and package substrate” is also reduced. As a result, the strain in the direction of semiconductor package corners upon solder bumps 36 in the vicinity of the semiconductor package corners that was noted as “great compressive strain” in FIG. 8 is changed to “little compressive strain.” However, solder bumps 36 in these locations are subject to great compressive strain from the effect of the mechanism “shear caused by the differences in the coefficients of linear expansion between the semiconductor package and package substrate,” and these solder bumps 36 are therefore not suited to the lead-out of interconnections 9 from lands 8, as in the first working example. Due to these factors, leading out interconnections from lands 8 in the same direction as in the first working example can also ensure the connection reliability between semiconductor package 2 and package substrate 5 in a configuration having a plurality of semiconductor elements 3 incorporated inside semiconductor package 2.

Eighth Working Example

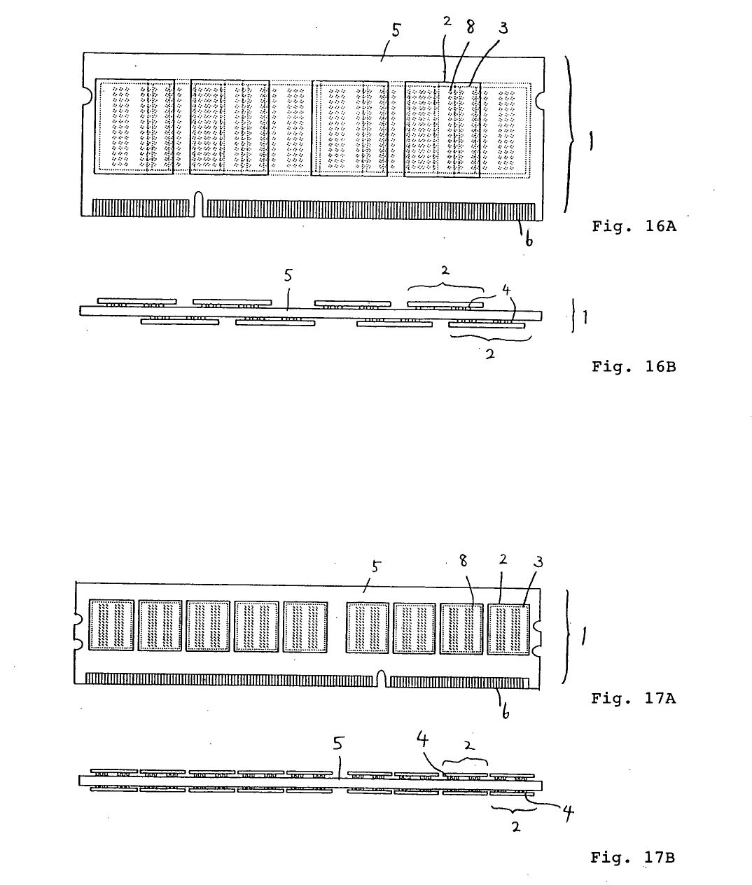

FIG. 16A is an overall plan view of the semiconductor device of the eighth working example of the present invention, and FIG. 16B is a side view of this semiconductor device.

The point of difference between the eighth working example and the first working example is the unsymmetrical arrangement of semiconductor packages 2 on the two surfaces of package substrate 5 in the eighth working example. As shown in the eighth working example, when the mounting positions of semiconductor packages 2 on package substrate 5 are not symmetrical, warping is generated in package substrate 5 by the heat load.

However, high-density mounting of semiconductor packages 2 on package substrate 5 prevents the extreme warping that occurs when semiconductor packages 2 are arranged on only one side of package substrate 5. The effect of warping of package substrate 5 has little effect upon the connection parts of semiconductor packages 2 and package substrate 5. Accordingly, leading out interconnections from lands 8 in the same direction as in the first working example can also ensure the connection reliability between semiconductor packages 2 and package substrate 5 in the eighth working example.

Ninth Working Example

FIG. 17A is an overall plan view of the semiconductor device of the ninth working example, and FIG. 17B is a side view of the semiconductor device.

As the point of difference between the ninth working example and the first working example, although the package substrate dimensions are based on the SODIMM standards in the first working example, package substrate 5 in the ninth working example is based on DIMM standards, whereby package substrate 5 is larger and has more mounted semiconductor packages.

Because warping of package substrate 5 is small in the ninth working example, the difference of the package substrate dimensions and the number of semiconductor packages 2 that are mounted has little effect on the connection parts between semiconductor packages 2 and package substrate 5. Accordingly, leading out interconnections from lands 8 in the same direction as in the first working example can again ensure the connection reliability between semiconductor packages 2 and package substrate 5 in the ninth working example.

Although the present invention has been described hereinabove with specificity based on each of working examples, the present invention is not limited to these working examples, and is of course open to various modifications that do not depart from the gist of the invention.

1. A semiconductor device that is provided with a semiconductor package and a package substrate having lands for electrically connecting to said semiconductor package by way of solder bumps, wherein:
a plurality of columns are formed on said package substrate, a plurality of said lands being arranged in each column,
at least one of said lands that make up said columns that are located on sides closest to main edges that make up the outer edges of said semiconductor package has an interconnection that extends from said land along the surface of said package substrate, and
said interconnection is formed with a contact portion with said land that is located closer to a line that passes through the center of said land and that is orthogonal to a line that joins the center of said land and the center of said semiconductor package than to the line that joins the center of said land and the center of said semiconductor package.

2. A semiconductor device that is provided with a semiconductor package and a package substrate having a plurality of lands for electrically connecting to said semiconductor package by way of solder bumps, wherein:
at least one of said lands that are located closest to areas of intersection of main sides that make up the outer edges of said semiconductor package has an interconnection that extends from said land along the surface of said package substrate, and
said interconnection is formed with a contact portion with said land that is located closer to a line that passes through the center of said land and that is orthogonal to a line that joins the center of said land and the center of said semiconductor package than to the line that joins the center of said land and the center of said semiconductor package.

3. A semiconductor device according to claim 1, wherein:
said semiconductor package is formed in a rectangular shape;
said lands are formed in a multiplicity of rows and a multiplicity of columns within the plane of projection of said semiconductor package; and
each of interconnections that contact said plurality of lands of the outermost columns and rows are formed such that contact portions with said lands are located close to lines that pass through the centers of said lands and that are orthogonal to lines that connect the centers of said lands with the center of said semiconductor package.

4. A semiconductor device according to claim 2, wherein:
said semiconductor package is formed in a rectangular shape;
said lands are formed in a multiplicity of rows and a multiplicity of columns within the plane of projection of said semiconductor package; and
each of interconnections that contact said plurality of lands of areas that are closest to corners of said semiconductor package are formed such that contact portions with said lands are located close to lines that pass through the centers of said lands and that are orthogonal to lines that connect the centers of said lands with the center of said semiconductor package.

5. A semiconductor device according to claim 1, wherein said lands are each formed in a circular shape having a diameter that is greater than the width of said interconnections, and said solder bumps are connected by contact with the upper surface and side surface of said lands.

6. A semiconductor device according to claim 1, wherein said lands comprise signal lands for conveying signals to said semiconductor package and power supply lands or ground lands that connect to a power supply or ground; and lands that have contact portions with said interconnections are said signal lands.

7. A semiconductor device according to claim 1, wherein said semiconductor packages are arranged on both main surfaces of said package substrate.

8. A semiconductor device according to claim 1, wherein said package substrate has outer terminals that are electrically connected to said semiconductor package and that are electrically connected to the outside.

9. A semiconductor device according to claim 1, said lands have a main surface that confronts said semiconductor package side of the lands and sidewalls that are adjacent to said main surface, and said solder bumps are formed so as to cover a portion of said side walls.

10. A semiconductor device that is provided with a semiconductor package and a package substrate having lands that electrically connect with said semiconductor package by way of solder bumps; wherein:
a multiplicity of said lands are arranged in a column and a plurality of said columns are formed on said package substrate;
at least one first land of said lands that make up said columns that are located closest to each of main sides that make up the outer edges of said semiconductor package has a first interconnection that extends from said first land along the surface of said package substrate;
said first interconnection is formed such that a contact portion with said first land is located closer to a line that passes through the center of said first land and that is orthogonal to a line that connects the center of said first land and the center of said semiconductor package than to the line that connects the center of said first land with the center of said semiconductor package;
at least one second land of said lands that make up columns that are arranged inwardly from said columns that are located closest to each of main sides that make up the outer edges of said semiconductor package has a second interconnection that extends from said second land and along the surface of said package substrate; and
said second interconnection is formed with a contact portion with said second land that is located closer to a line that passes through the center of said second land and that is orthogonal to a line that connects the center of said second land with the center of said semiconductor package than to the line that connects the center of said second land to the center of said semiconductor package.

11. A semiconductor device according to claim 2, wherein said lands are each formed in a circular shape having a diameter that is greater than the width of said interconnections, and said solder bumps are connected by contact with the upper surface and side surface of said lands.

12. A semiconductor device according to claim 2, wherein said lands comprise signal lands for conveying signals to said semiconductor package and power supply lands or ground lands that connect to a power supply or ground; and lands that have contact portions with said interconnections are said signal lands.

13. A semiconductor device according to claim 2, wherein said semiconductor packages are arranged on both main surfaces of said package substrate.

14. A semiconductor device according to claim 2, wherein said package substrate has outer terminals that are electrically connected to said semiconductor package and that are electrically connected to the outside.

15. A semiconductor device according to claim 2, said lands have a main surface that confronts said semiconductor package side of the lands and sidewalls that are adjacent to said main surface, and said solder bumps are formed so as to cover a portion of said side walls.
